(19) United States
(12) Patent Application Publication
(10) Pub. No.: US 2026/0062801 A1
(43) Pub. Date: Mar. 5, 2026

(54) METHOD OF SUPPLYING RAW MATERIAL GAS, APPARATUS FOR SUPPLYING RAW MATERIAL GAS, AND APPARATUS FOR FORMING FILM ON SUBSTRATE

(71) Applicant: Tokyo Electron Limited, Tokyo (JP)

(72) Inventor: Takeshi ITATANI, Nirasaki City (JP)

(21) Appl. No.: 19/386,305

(22) Filed: Nov. 12, 2025

Related U.S. Application Data
(63) Continuation of application No. PCT/JP2024/017161, filed on May 8, 2024.

(30) Foreign Application Priority Data
May 22, 2023 (JP) 2023-084041

(51) Int. Cl. C23C 16/448; C23C 16/06; C23C 16/455; C23C 16/52

(52) U.S. Cl. CPC C23C 16/448; C23C 16/06; C23C 16/45525; C23C 16/52

(57) ABSTRACT

A method of supplying a raw material gas includes: supplying a power to at least one heater provided at a raw material container in which a solid raw material is accommodated and heating an inside of the raw material container to sublimate the solid raw material; supplying a carrier gas to the raw material container being heated by the heater and mixing the carrier gas with the sublimated solid raw material to supply a mixed gas as the raw material gas to a consumption zone in which a substrate is disposed; and acquiring an index value having a corresponding relationship with a remaining amount of the solid raw material, wherein, in sublimating the solid raw material, a power corresponding to the index value is supplied to the heater, based on a corresponding relationship between the index value, which is preset, and the power supplied to the heater.

### CROSS-REFERENCE TO RELATED APPLICATIONS

This application is a bypass continuation application of International Patent Application No. PCT/JP2024/017161 having an international filing date of May 8, 2024 and designating the United States, the international application being based upon and claiming the benefit of priority from Japanese Patent Application No. 2023-084041, filed on May 22, 2023, the entire contents of which are incorporated herein by reference.

### TECHNICAL FIELD

The present disclosure relates to a method of supplying a raw material gas, an apparatus for supplying a raw material gas, and an apparatus for forming a film on a substrate.

### BACKGROUND

For example, when a metal film or the like is formed on a substrate by chemical vapor deposition (CVD), a raw material gas obtained from a solid raw material may be used. Specifically, the solid raw material accommodated in a raw material container is heated and sublimated and is mixed with a carrier gas supplied from a carrier gas source to obtain the raw material gas. Thereafter, the raw material gas is supplied into a processing container accommodating the substrate, thereby forming the film.

Patent Document 1 discloses calculating a flow rate of a raw material gas by measuring a gas pressure in a process gas supply path with a pressure gauge. Further, a control method is disclosed in which, when the calculated flow rate of the raw material gas differs from a set flow rate according to a recipe, a temperature of a raw material container is adjusted by a temperature control program so as to adjust the flow rate of the raw material gas and achieve a desired film thickness.

### PRIOR ART DOCUMENTS

### Patent Documents

Patent Document 1: Japanese Laid-Open Patent Publication No. 2008-240119

### SUMMARY

According to one embodiment of the present disclosure, a method of supplying a raw material gas includes: supplying a power to at least one heater provided at a raw material container in which a solid raw material is accommodated and heating an inside of the raw material container to sublimate the solid raw material; supplying a carrier gas to the raw material container being heated by the at least one heater and mixing the carrier gas with the sublimated solid raw material to supply a mixed gas as the raw material gas to a consumption zone in which a substrate is disposed; and acquiring an index value having a corresponding relationship with a remaining amount of the solid raw material, wherein, in sublimating the solid raw material, a power corresponding to the index value is supplied to the at least one heater, based on a corresponding relationship between the index value, which is preset, and the power supplied to the at least one heater.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plane view illustrating a substrate processing system according to an embodiment of the present disclosure.

FIG. 2 is a longitudinal cross-sectional side view illustrating an Ru film formation processing module of the substrate processing system.

FIG. 3 is a longitudinal cross-sectional side view illustrating a raw material gas supply apparatus attached to the Ru film formation processing module.

FIG. 4 is a block diagram illustrating the raw material gas supply apparatus according to a comparative example.

FIG. 5 is a graph illustrating a change in a film formation rate in a raw material gas supply method according to the comparative example.

FIG. 6 is a graph illustrating changes in powers supplied to respective heaters in the raw material gas supply method.

FIG. 7 is a block diagram illustrating an electric configuration of a raw material gas supply apparatus according to the embodiment.

FIG. 8 is a functional diagram illustrating a function of the raw material gas supply apparatus.

FIG. 9A is a graph illustrating a change in a power supplied to a side heater in a raw material gas supply method of the embodiment.

FIG. 9B is a graph illustrating a change in a power supplied to a bottom heater in the raw material gas supply method.

FIG. 9C is a graph illustrating a change in a power supplied to a top heater in the raw material gas supply method.

FIG. 10 is a graph illustrating a change in a film formation rate in the raw material gas supply method.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

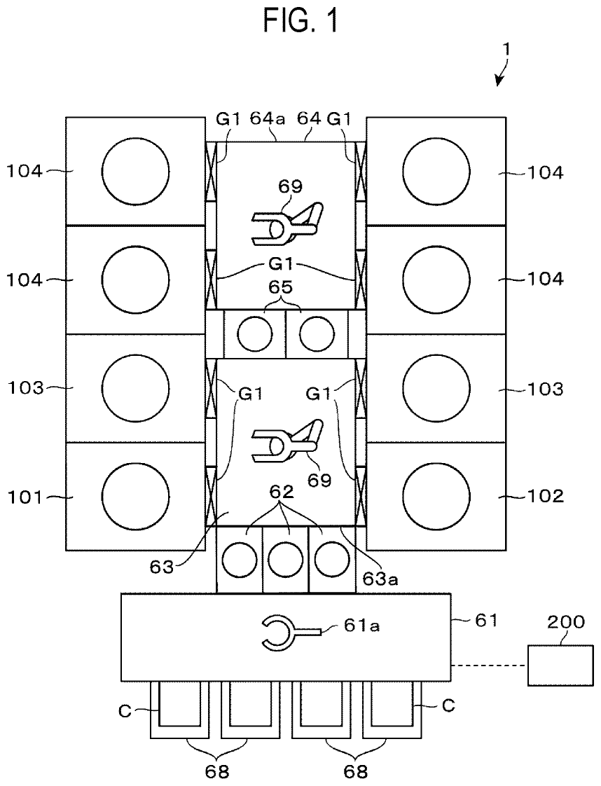

A substrate processing system 1 shown in FIG. 1 is configured to perform a film formation process of forming a titanium nitride (TiN) film and a ruthenium (Ru) film as barrier metals on a wafer W. The substrate processing system 1 is configured as a multi-chamber system including processing modules 101, 102, 103, and 104 that perform an oxide film removal process, which is a pre-processing process for film formation, and TiN film and Ru film formation processes. Among the two types of processing modules 101 and 102 that perform the oxide film removal process, the chemical oxide removal (COR) processing module 101 performs a COR process for modifying an oxide film formed on a surface of a metal base (e.g., an Si layer described later) into a reaction product. The post heat treatment (PHT) processing module 102 performs a PHT process for sublimating the reaction product. The TiN film formation processing module 103 performs a TiN film formation process, and the Ru film formation processing module 104 performs an Ru film formation process.

In a case in which an Ru film is directly formed on the metal base without forming the barrier metals such as a TiN film and the like, an oxide film may be removed by argon (Ar) gas plasma or H₂ gas plasma, instead of performing the COR process and the PHT process. In this case, the substrate processing system 1 is provided with a plasma processing module for oxide film removal instead of the COR processing module 101 and the PHT processing module 102.

Returning to the description of FIG. 1, in addition to the processing modules 101 to 104, the substrate processing system 1 is provided with a loader module 61, load lock modules 62, first and second vacuum transfer modules 63 and 64, and connection modules 65.

As illustrated in FIG. 1, the loader module 61, the load lock modules 62, the first vacuum transfer module 63, the connection modules 65, and the second vacuum transfer module 64 are provided in this order along a straight line in a front-rear direction. In the following description of the substrate processing system 1, a side at which the loader module 61 is located is referred to as a front side, and a side at which the second vacuum transfer module 64 is located is referred to as a rear side.

The loader module 61 includes a housing, the interior of which is at atmospheric pressure, a wafer transfer mechanism 61a provided inside the housing, and load ports 68. In this example, four load ports 68 are provided side by side on the front side of the housing in a left-right direction. A transfer container C for storing the wafer W, called a front opening unified pod (FOUP), is placed on each of the load ports 68. The transfer mechanism 61a is configured, for example, by an articulated arm movable in the left-right direction and is capable of transferring the wafer W between the transfer container C, placed on each of the load ports 68, and each of the load lock modules 62.

In this example, three load lock modules 62 are provided side by side in the left-right direction when viewed from the front side. Each of the load lock modules 62 includes a housing, and the housing is connected to the loader module 61 and the first vacuum transfer module 63 via gate valves (not shows), which are provided respectively on the front side and the rear side of the housing. When the gate valves on the front side and the rear side of the housing are closed, a pressure inside the housing is capable of being varied between an atmospheric pressure and a vacuum pressure. A stage on which the wafer W is placed is provided inside the housing, and the stage is configured to allow transfer of the wafer W to and from the transfer mechanism 61a and a vacuum transfer mechanism 69 which is described later, both of which access the corresponding load lock module 62.

The first vacuum transfer module 63 and the second vacuum transfer module 64 include the same configuration and include housings 63a and 64a and the transfer mechanisms 69 provided inside the housings 63a and 64a, respectively. One end of an exhaust pipe is connected to the housings 63a and 64a. Insides of the housings 63a and 64a are maintained in a vacuum atmosphere by an exhaust mechanism connected via the exhaust pipe. The exhaust mechanism is, for example, a turbomolecular pump.

In this example, two connection modules 65 are provided side by side in the left-right direction. Each of the connection modules 65 includes a housing, and the housing is connected to the housings 63a and 64a of the vacuum transfer modules 63 and 64. By exhaust performed by the exhaust mechanism, an inside of the housing of each of the connection modules 65 becomes a vacuum atmosphere having the same pressure as the insides of the housings 63a and 64a. A stage configured to allow transfer of the wafer W placed on the stage to and from the vacuum transfer mechanism 69 described later is provided inside the housing of each of the connection modules 65.

When viewed from the front side, the COR processing module 101 and the PHT processing module 102 are respectively connected to left and right sides on the front side of the housing 63a of the first vacuum transfer module 63 via gate valves G1. The COR processing module 101 is disposed on the left side, and the PHT processing module 102 is disposed on the right side. In this way, one COR processing module 101 and one PHT processing module 102 are provided around the first vacuum transfer module 63.

When viewed from the front side, the TiN film formation processing modules 103 are respectively connected to left and right sides on an inner side of the housing 63a of the first vacuum transfer module 63 via gate valves G1. In this way, two TiN film formation processing modules 103 are provided around the first vacuum transfer module 63. Transfer of the wafer W between the processing modules 101 to 103 and the load lock modules 62 is performed by the vacuum transfer mechanism 69 configured, for example, by an articulated arm movable in the front-rear and left-right directions. The vacuum transfer mechanism 69 identically performs transfer of the wafer W between these processing modules 101 to 103 and the connection modules 65 or among the processing modules 101 to 103.

When viewed from the front side, two Ru film formation processing modules 104, arranged in the front-rear direction, are respectively connected to left and right sides of the housing 64a of the second vacuum transfer module 64 via gate valves G1. Transfer of the wafer W between the Ru film formation processing modules 104 and the connection modules 65 is performed, for example, by the vacuum transfer mechanism 69 of the second vacuum transfer module 64. In this way, four Ru film formation processing modules 104 are provided around the second vacuum transfer module 64.

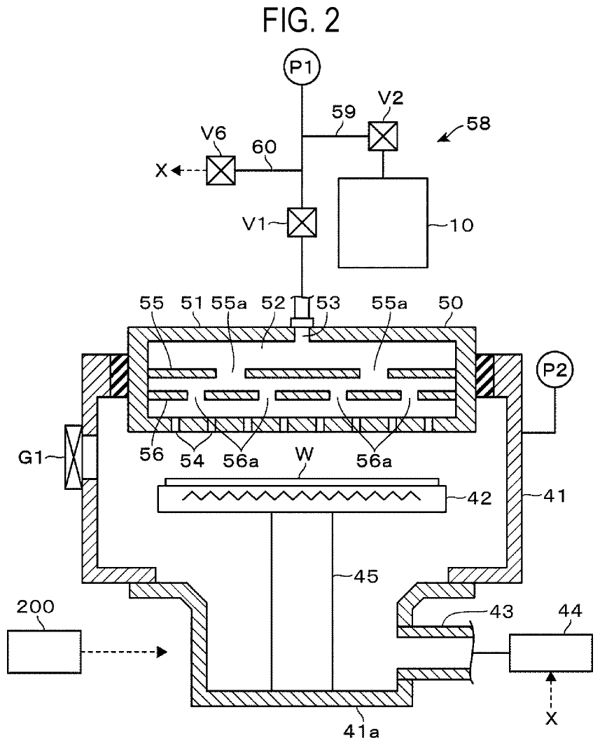

Like the Ru film formation processing module 104 shown in FIG. 2 as a representative of the processing modules 101 to 104, each of the processing modules 101 to 104 includes a processing container 41 whose interior is exhausted to become a vacuum atmosphere, and a substrate stage 42 that is provided inside the processing container 41 to place the wafer W. Each processing process is performed inside the processing container 41.

The substrate processing system 1 includes a controller 200, which is a computer, and the controller 200 includes a program. The program incorporates instructions (steps) for performing the above-described processing processes of the wafer W and transfer processes of the wafer W. The program is stored in a non-transitory computer-readable storage medium, for example, a compact disc, a hard disk, a DVD, or a non-volatile memory, and is read from the storage medium and installed in the controller 200.

The controller 200 outputs a control signal to each part of the substrate processing system 1 according to the program to control an operation of each part. Specifically, operations such as operations of the processing modules 101 to 104, opening and closing of the gate valves G1, operations of the transfer mechanism 61a or the vacuum transfer mechanism 69, an operation of the exhaust mechanism, and a pressure switching inside the load lock modules 62 and the like. Specifically, control of the operations of the processing modules 101 to 104 includes, for example, control of a temperature of the wafer W by power supply to a heater described later, control of supply or cutoff of each gas into the processing container 41, and the like.

Herein, a transfer route of the wafer W in the substrate processing system 1 is described. The wafer W is first transferred in order of the transfer container C→loader module 61→load lock module 62→first vacuum transfer module 63→COR processing module 101. The wafer W that has undergone the COR process in the COR processing module 101 is then transferred in order of the COR processing module 101→first processing module 63→PHT processing module 102.

Then, the wafer W that has undergone the PHT process in the PHT processing module 102 is transferred in order of the PHT processing module 102→first vacuum transfer module 63→TiN film formation processing module 103. The wafer W that has undergone the TiN film formation process in the TiN film formation processing module 103 is transferred in order of the TiN film formation processing module 103→first vacuum transfer module 63→connection module 65→second vacuum transfer module 64→Ru film formation processing module 104. The wafer W that has undergone the Ru film formation process in the Ru film formation processing module 104 is transferred in order of the Ru film formation processing module 104→second vacuum transfer module 64→connection modules 65→first vacuum transfer module 63→load lock module 62→loader module 61 and is returned to the transfer container C.

Although not individually shown, a brief description is given of the COR processing module 101, the PHT processing module 102, and the TiN film formation processing module 103. Each of these processing modules 101 to 103 includes a processing container, a substrate stage disposed inside the processing container, a substrate heater provided at the substrate stage, and various gas supply mechanisms.

The substrate heater of the COR processing module 101 is configured to heat the wafer W placed on the substrate stage to a heated temperature of 60 degrees C. or higher, for example, by supplying and circulating a temperature control fluid through a conduit formed within the substrate stage. In addition, the COR processing module 101 includes, as the gas supply mechanism, a mixed gas supply mechanism configured to supply a mixed gas of hydrogen fluoride (HF) gas, ammonia (NH₃) gas, and an inert gas for modifying an oxide film. The mixed gas supply mechanism is configured to supply various gases to a shower head provided in the processing container.

The substrate heater of the PHT processing module 102 uses, for example, resistive heating and is configured to heat the wafer W to a temperature higher than that of the wafer W during the COR process. An inert gas supply, which is the gas supply mechanism of the PHT processing module 102, is configured, for example, to supply nitrogen (N₂) gas, which is an inert gas, directly into the processing container without passing through the shower head. By supplying the inert gas, it is possible for a reaction product sublimated inside the processing container to be quickly purged, and to adjust a pressure inside the processing container.

The TiN film formation processing module 103 forms a TiN film, for example, by thermal atomic layer deposition (ALD). The substrate heater of the TiN film formation processing module 103 heats the wafer W to, for example, 700 degrees C. to 1000 degrees C. The gas supply mechanism is configured to alternately supply a raw material gas containing a raw material of the TiN film and a reaction gas reacting with the raw material gas into the processing container, for example, with supply of a purge gas therebetween. For example, the raw material gas is titanium tetrachloride (TiCl₄) gas, and the reaction gas is ammonia (NH₃) gas.

Hereinafter, a configuration of the Ru film formation processing module 104 is described with reference to FIG. 2. FIG. 2 is a longitudinal cross-sectional side view illustrating the Ru film formation processing module 104. The Ru film formation processing module 104 continuously supplies a raw material gas containing Ru₃(CO)₁₂ gas (hereinafter also referred to as DCR gas) to a surface of the wafer W and forms an Ru film by a thermal CVD method. The processing container 41 previously described is an approximately cylindrical container, with an upper surface and a lower surface thereof opened. The substrate stage 42 is provided inside the processing container 41 for holding the wafer W approximately horizontally. An N₂ gas supply, which is not shown, is connected to the processing container 41 and is configured to appropriately supply N₂ gas into the processing container 41.

An opening on a lower surface side of the processing container 41 is provided with a bottom cover 41a, and a vacuum exhaust path 43 is connected to the bottom cover 41a via an exhaust port. A vacuum exhauster 44 composed of, for example, a vacuum pump is configured to execute vacuum-exhaust of gas within the processing container 41 and is provided downstream of the vacuum exhaust path 43. A pressure control valve, for example, an automatic pressure controller (APC) valve, which is not shown, is interposed between the processing container 41 of the vacuum exhaust path 43 and the vacuum exhauster 44. An opening/closing operation of the APC valve is controlled based on a result of measuring a pressure inside the processing container 41 by a pressure measurer P2 connected to the processing container 41.

A loading/unloading port for loading or unloading the wafer W to or from the second vacuum transfer module 64 is formed on a side surface of the processing container 41, and this loading/unloading port is configured to be opened and closed by the gate valve G1. The above-described substrate stage 42 is, for example, made of aluminum nitride or quartz, and a substrate heater composed of a resistive heating element for heating the wafer W is embedded therein. The substrate heater is powered by a power supply, which is not shown, thereby generating heat and heating the wafer W placed on the substrate stage 42 to a temperature in a range of, for example, 100 degrees C. to 250 degrees C.

A supporter 45 extending downward is connected to a center of a bottom surface of the substrate stage 42. The supporter 45 is disposed to pass through the bottom cover 41a. On the substrate stage 42, for example, three transfer pins, which are not shown, are provided so as to penetrate the substrate stage 42 in a retractable manner on an upper surface of the substrate stage 42. The transfer pins provided on the substrate stage 42 transfer the wafer W to and from the vacuum transfer mechanism 69 to place the wafer W on the substrate stage 42.

A shower head 50 is hermetically installed in an opening on an upper surface side of the processing container 41, for example, via a heat-resistant insulating member. The shower head 50 is positioned facing the wafer W placed on the substrate stage 42. The shower head 50 includes, for example, a cylindrical housing 51 and a diffusion chamber 52 which is provided inside the housing 51 to diffuse a raw material gas. A gas supply hole 53 to which a gas supply mechanism 58 described later is connected to supply the raw material gas is formed at an upper surface of the housing 51. Discharge holes 54 for discharging the supplied raw material gas toward the wafer W is formed at a lower surface of the housing 51.

The diffusion chamber 52 is provided with diffusion plates 55 and 56 that are spaced apart from each other to divide the diffusion chamber 52 into three spaces in a vertical direction. The diffusion plates 55 and 56 are respectively formed with through holes 55a and through holes 56a that constitute a flow path for the raw material gas. Each of the through holes 56a of the diffusion plate 56 is misaligned so as not to face the discharge holes 54 formed at the lower surface of the housing 51. Similarly, each of the through holes 55a of the diffusion plate 55 is misaligned so as not to face the through holes 56a of the diffusion plate 56. By arranging the through holes 55a and 56a on the diffusion plates 55 and 56, respectively, in the manner described above, the raw material gas is prevented from flowing straight through the through holes 55a and 56a and the discharge holes 54, allowing the raw material gas to be sufficiently diffused within the housing 51 constituting the shower head 50 and to be uniformly discharged from each of the discharge holes 54.

The gas supply mechanism 58 includes a gas supply path 59 and a raw material gas supply source 10 which is provided upstream of the gas supply path 59 to supply the raw material gas. A downstream end of the gas supply path 59 is connected to the gas supply hole 53 provided on an upper surface of the shower head 50. Valves V1 and V2 are provided downstream of the raw material gas supply source 10 in the gas supply path 59. Among the valves V1 and V2, the valve V1 disposed on a downstream side is, for example, a shutoff valve and performs a supply or cutoff operation of the raw material gas into the processing container 41.

Meanwhile, the valve V2 serves to perform an operation of discharging the raw material gas in the raw material gas supply source 10 to an outside. A pressure measurer P1 for measuring a pressure of the raw material gas flowing between the valves V1 and V2 in the gas supply path 59 is connected at a corresponding location. Further, an exhaust path 60 provided with a valve V6 is connected between the valves V1 and V2 in the gas supply path 59. A downstream end of the exhaust path 60 is connected to the vacuum exhauster 44, thereby allowing the raw material gas to be discharged directly toward the vacuum exhauster 44 without passing through the processing container 41. In addition, the gas supply path 59 and the exhaust path 60 are provided with heaters (not shown), and the heaters heat the entire gas supply path 59 and exhaust path 60, which include the valves V1, V2, and V6. This prevents the raw material gas from re-solidifying and attaching to the gas supply path 59 and the exhaust path 60, which include the valves V1, V2, and V6.

The controller 200 described previously also has a function of controlling the Ru film formation process in the Ru film formation processing module 104. The controller 200 includes a memory 201 and a program for executing each film formation process and operates each component within the Ru film formation processing module 104. Specifically, the controller 200 includes a program for executing a raw material gas supply process described later and operates each component of the gas supply mechanism 58.

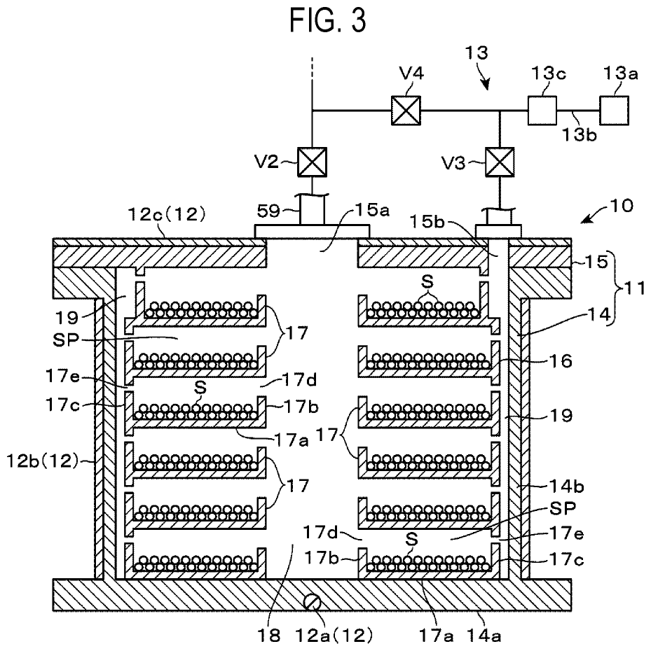

Hereinafter, the raw material gas supply source 10 of the Ru film formation processing module 104 according to the present disclosure is described in detail with reference to FIG. 3. FIG. 3 is a longitudinal cross-sectional side view of the raw material gas supply source 10, with illustration of temperature sensors TCa, TCb, and TCc and power supplies 21a, 21b, and 21c, which are described later, omitted. The raw material gas supply source 10 includes a raw material container 11 that accommodates a solid raw material S for generating the DCR gas contained in a raw material gas, a plurality of heaters 12 provided at the raw material container 11 to heat the solid raw material S, and a carrier gas supply 13. The solid raw material S is, for example, solid Ru₃(CO)₁₂ formed into granules.

The carrier gas supply 13 is configured to supply, for example, carbon monoxide (CO) gas as a carrier gas to the raw material container 11. Since the CO gas functions to suppress decomposition of solid Ru₃(CO)₁₂ and also suppress acceleration of an Ru film formation rate caused by the DCR gas, which is prone to resolidification, it is desirable to supply the CO gas at a preset flow rate ratio with respect to the DCR gas. The carrier gas supply 13 includes a CO gas supply source 13a, an introduction path 13b connecting the supply source 13a to the raw material container 11, and a flow rate controller 13c provided in the introduction path 13b.

The flow rate controller 13c corresponds to a measurer that includes a flow rate meter for the CO gas and measures a supplied amount of the CO gas. The introduction path 13b branches into two, for example, on a downstream side of the flow rate controller 13c, with one downstream end connected to the raw material container 11 via a valve V3, and the other downstream end connected to a downstream side of the valve V2 in the gas supply path 59 via a valve V4. By this configuration, the carrier gas supply 13 is configured to switch between a flow path that supplies the carrier gas to the raw material container 11 and a flow path that bypasses the raw material container 11 and directly supplies the carrier gas to the gas supply path 59.

The raw material container 11 includes a main body 14 that has a roughly cylindrical shape and opens at an upper end and a top cover 15 that is detachably or hermetically installed on the upper end of the main body 14. The top cover 15 constitutes an upper surface of the raw material container 11 and has an approximately disc shape. A raw material gas discharge port 15a for discharging the raw material gas generated in the raw material container 11 to the gas supply path 59 is formed at a central portion of the top cover 15. In addition, a carrier gas supply port 15b for supplying the CO gas to the raw material container 11 is formed at a side end of the top cover 15. A flow path cross-sectional area of the carrier gas supply port 15b is smaller than a flow path cross-sectional area of the raw material gas discharge port 15a.

The main body 14 includes a bottom 14a constituting a bottom surface of the raw material container 11 and a side 14b constituting a side surface of the raw material container 11. The bottom 14a has a disc shape and is expanded outward relative to a lower end of the side 14b. An upper end of the side 14b is expanded outward to constitute a flange and is configured such that the top cover 15 having the same diameter is detachably installed. The raw material container 11 is configured such that, when the top cover 15 is separated, it is possible to open an internal space of the main body 14 upward.

A raw material loader 16 for holding the granular solid raw material S is disposed in an internal space of the raw material container 11. The raw material loader 16 is formed so as to protrude downward from a lower surface of the top cover 15. An up-down direction of the raw material gas supply source 10 is the same as a vertical direction, and a dimension in the up-down direction may be referred to as height or a depth. A height of the raw material loader 16 is approximately the same as a depth of an internal space of the main body 14. In addition, the raw material loader 16 is accommodated within the raw material container 11 by attaching the top cover 15 to the main body 14. In this case, a lower surface of the raw material loader 16 is disposed in contact with the bottom 14a of the main body 14. The raw material loader 16 is separated from the internal space of the main body 14 by removing the main body 14 from the top cover 15 and being lifted upward, thereby allowing appropriate replenishment of the solid raw material.

The raw material loader 16 has an approximately cylindrical shape with a diameter smaller than that of the internal space of the raw material container 11. The raw material loader 16 is configured by a plurality of stages, for example, six stages, of trays 17 spaced apart from each other, for example, in the up-down direction. The trays 17 correspond to raw material holding trays in the present embodiment. Each of these trays 17 has approximately the same annular shape and is disposed around a cylindrical central flow path 18 that extends in the up-down direction. The central flow path 18 is disposed immediately below the raw material gas discharge port 15a of the top cover 15 and has a flow path cross-sectional area approximately equal to that of the raw material gas discharge port 15a.

Specifically, the tray 17 includes an annular bottom 17a disposed horizontally, an inner protrusion 17b provided on an inner side of the bottom 17a, and a cylindrical outer wall 17c formed to extend downward from the lower surface of the top cover 15 to hold an outer periphery of the bottom 17a. The inner protrusion 17b is installed to project upward from the bottom 17a. By the bottom 17a, the inner protrusion 17b, and the outer wall 17c, each of the trays 17 constitutes an annular recess which is open upward. Within this annular recess, it is possible to stably hold a large number of granular solid raw materials S while preventing the solid raw materials S from falling from each of the trays 17. Spaces above the trays 17 spaced apart from each other in the up-down direction constitute raw material gas generation spaces SP for sublimating the solid raw material S to generate DCR gas and mixing the DCR gas with the CO gas to obtain a raw material gas. The raw material gas generation spaces SP have approximately the same volume as each other.

The inner protrusions 17b formed on inner peripheral sides of the trays 17 form annular gaps 17d with the trays 17 of upper sides thereof or with the top cover 15. Each of the raw material gas generation spaces SP is connected to the central flow path 18 through these gaps 17d. Meanwhile, an upper end of the uppermost cylindrical outer wall 17c is connected to the lower surface of the top cover 15. That is, each of the trays 17 is provided so as to be suspended from the top cover 15 via the outer wall 17c. The outer wall 17c surrounding the uppermost tray 17 is disposed inward relative to the outer walls 17c of a region located below the uppermost tray 17. In addition, carrier gas introduction holes 17e that penetrate from an inner side toward an outer side is formed in regions corresponding to the raw material gas generation spaces SP of the outer walls 17c. The carrier gas introduction holes 17e are uniformly formed in the annular outer walls 17c at equal angular intervals, for example, at intervals of 30 degrees.

As already described, the bottom 17a, which is the lower surface of the raw material loader 16, is disposed in contact with the bottom 14a of the main body 14. A cylindrical carrier gas flow path 19 is formed between outer surfaces of the cylindrical outer walls 17c and an inner surface of the main body 14. An upper end of the carrier gas flow path 19 is in communication with the carrier gas supply port 15b. A width of the carrier gas flow path 19 in a radial direction is configured to be larger at the outer wall 17c of the uppermost tray 17, which is the upper end, than in a region located below the uppermost tray 17.

As already described, the raw material container 11 is provided with the plurality of heaters 12. Specifically, the raw material container 11 includes a bottom heater 12a installed at the bottom 14a, a side heater 12b installed at the side 14b, and a top heater 12c installed at the top cover 15. Each of the heaters 12a to 12c is supplied with power by respective power supplies 21a to 21c described below. The bottom heater 12a includes, for example, a single linear resistive heating element and is embedded in a radial direction of the bottom 14a.

The side heater 12b and the top heater 12c include, for example, sheet-like resistive heating elements. The side heater 12b is disposed to cover an entire outer surface of the side 14b, and the top heater 12c is disposed to cover an entire upper surface of the top cover 15. A joint that constitutes an upstream end of the gas supply path 59 is hermetically attached to a central side of the top cover 15, and the gas supply path 59 is connected to the central flow path 18 via the raw material gas discharge port 15a. A joint that constitutes a downstream end of the introduction path 13b is hermetically attached to a side end of the top cover 15, and the introduction path 13b is connected to the carrier gas flow path 19 via the carrier gas supply port 15b. The top heater 12c is provided with openings corresponding to the raw material gas discharge port 15a and the carrier gas supply port 15b.

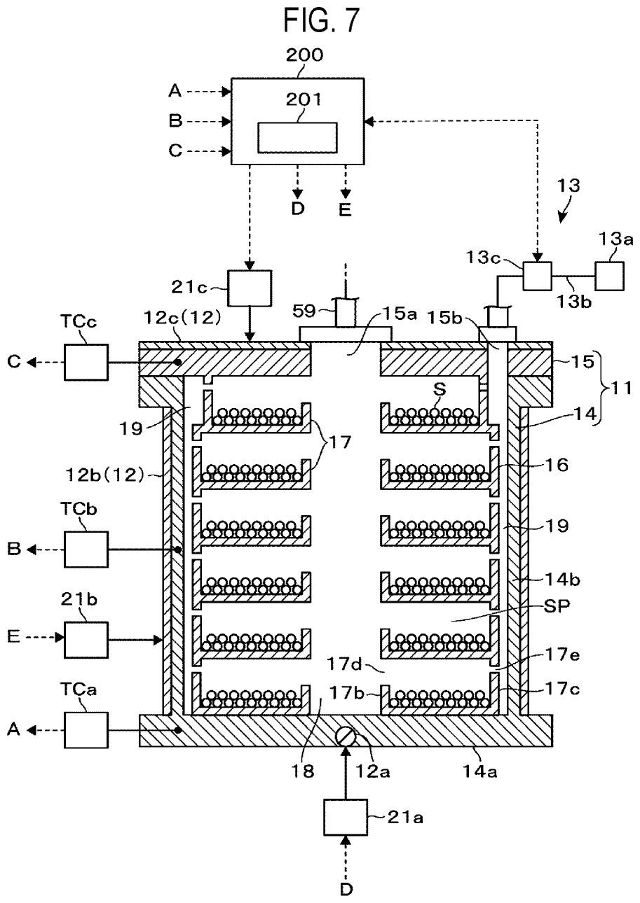

These heaters 12 (12a to 12c) heat the raw material container 11 to heat the solid raw material S accommodated in the raw material container 11 to a preset temperature, thereby sublimating the solid raw material S to generate the DCR gas. In indirectly controlling a temperature of the solid raw material S in this way, the power supplies 21a to 21c that supply powers are connected to the heaters 12a to 12c, respectively. In correspondence with the respective heaters 12a to 12c of the raw material container 11, temperature sensors TCa, TCb, and TCc, as shown in FIG. 7, are provided. The temperature sensors TCa, TCb, and TCc are installed to measure temperatures of the bottom 14a, the side 14b, and the top cover 15, respectively.

The power supplies 21a, 21b, and 21c are configured to supply adjusted powers to the respective heaters 12a, 12b, and 12c. The power supplies 21a to 21c and the temperature sensors TCa to TCc are connected to the controller 200 described above. The controller 200 operates the power supplies 21a to 21c so as to adjust the temperatures of the bottom 14a, the side 14b, and the top cover 15 to respective set temperatures. In addition, the controller 200 performs various control operations in the raw material gas supply process. The controller 200 also operates the flow rate controller 13c so as to flow a preset supply flow rate of the CO gas.

The raw material gas supply source 10 including the configuration described above corresponds to the “apparatus for supplying a raw material gas” in the present embodiment, and the Ru film formation processing module 104 including the raw material gas supply source 10 corresponds to the “apparatus for forming a film on a substrate” in the present embodiment.

Before describing a raw material gas supply method of the present disclosure, a raw material gas supply method of a comparative example that utilizes a general feedback control, which is contrasted with the present method, is described.

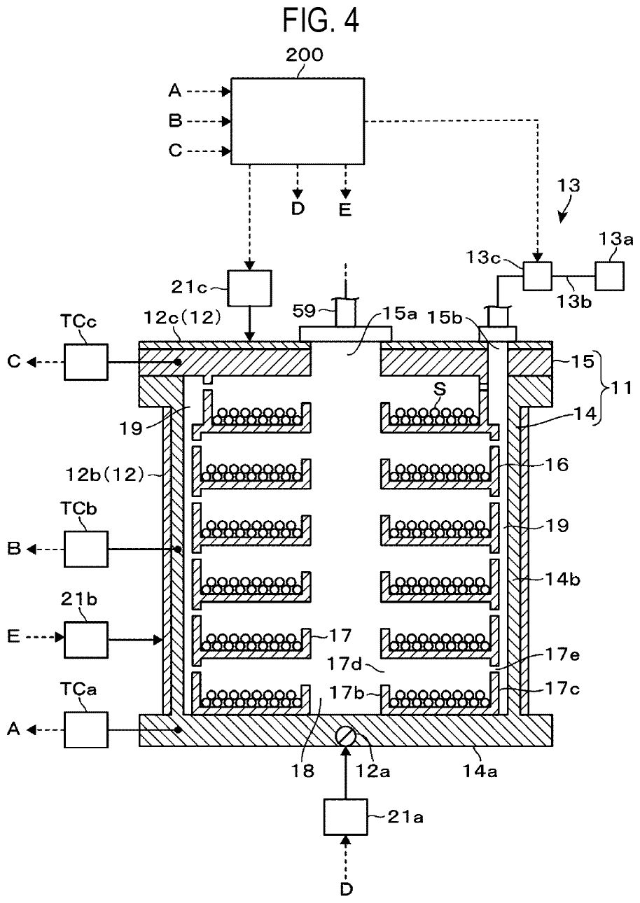

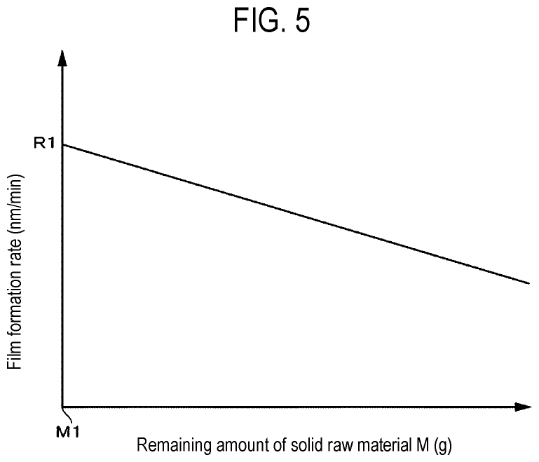

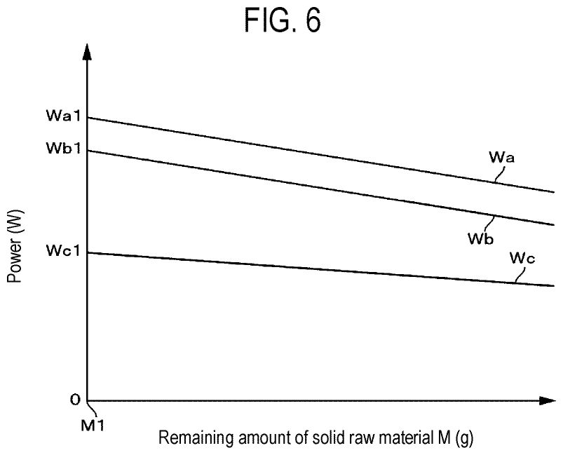

A raw material gas supply process of the comparative example is described with reference to FIGS. 4 to 6. FIG. 4 is a block diagram illustrating a raw material gas supply source of the comparative example, with illustration of a portion of a downstream end at which the introduction path 13b is branched is omitted. FIG. 5 is a graph illustrating a change in an Ru film formation rate (a thickness of an Ru film formed per unit time) with respect to a remaining amount of a solid raw material in the raw material gas supply process according to the comparative example. FIG. 6 is a graph illustrating changes in powers Wa, Wb, and Wc supplied to the respective heaters 12a, 12b, and 12c with respect to the remaining amount of the solid raw material in the same process.

In the raw material gas supply method according to the comparative example, the controller 200 performs a feedback control to increase or decrease powers supplied to the respective heaters 12 from the power supplies 21a to 21c, based on values measured by the temperature sensors TCa, TCb, and TCc, so that the temperatures of the bottom 14a, the side 14b, and the top cover 15 approach respective set temperatures. In this raw material gas supply method, the solid raw material S is sublimated by heating the solid raw material S via the raw material container 11 (the bottom 14a, the side 14b, and the top cover 15) to generate the DCR gas. The respective temperature set values for the bottom 14a, the side 14b, and the top cover 15 are set based on a preliminary experiment etc., so that the Ru film formation rate remains constant under the condition of a predetermined supply flow rate of the CO gas.

However, when the raw material gas is supplied while performing the feedback control under the above condition, it was found, as shown in FIG. 5, that, there is a case in which, as the film formation process proceeds, the remaining amount of the solid raw material S in the raw material container 11 decreases and thus the Ru film formation rate decreases. In the case in which the Ru film formation rate decreases, it was found that the powers supplied to the respective heaters 12a to 12c also tend to decrease in accordance with the reduction in the Ru film formation rate, even though the temperature set values are not changed.

Presumably, the reason why the above-described phenomenon occurs is that, as the solid raw material S sublimates and the remaining amount of the solid raw material S decreases, a total heat capacity of the raw material container 11 and the solid raw material S decreases. Accordingly, a heat capacity required to maintain the temperatures of the bottom 14a, the side 14b, and the top cover 15 constituting the raw material container 11 at the previously described temperature set values also decreases, and the powers supplied to the respective heaters 12a to 12c correspondingly decrease. However, when the powers supplied to the respective heaters 12a to 12c decrease, it is considered that, even though the temperatures of the bottom 14a, the side 14b, and the top cover 15 are maintained at the temperature set values, temperatures at surfaces of the solid raw material S held by the trays 17 are significantly lower than values detected by the temperature sensors TCa, TCb, and TCc. As a result, it is also considered that a concentration of the DCR gas decreases due to a reduced amount of sublimation from the solid raw material S, which may in turn cause a reduction in the film formation rate. Taking these phenomena into account, the raw material gas supply method according to the present disclosure adjusts the film formation rate by upwardly correcting the powers supplied to the respective heaters 12, which decrease as a remaining amount of the raw material gas decreases.

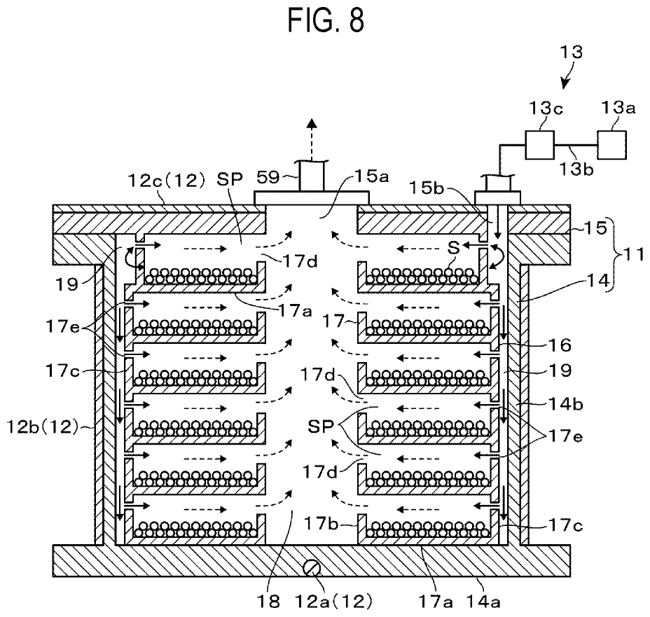

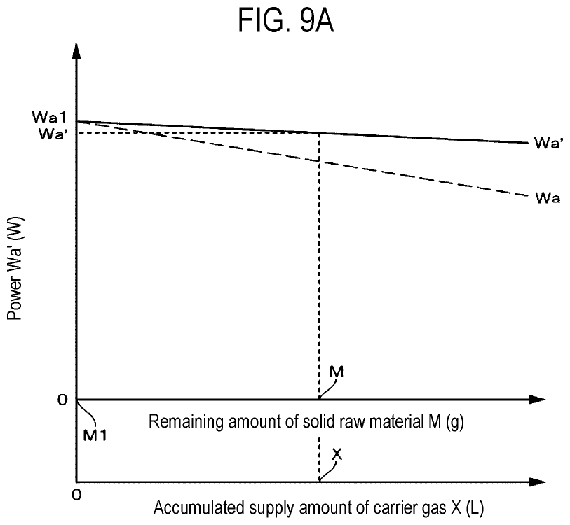

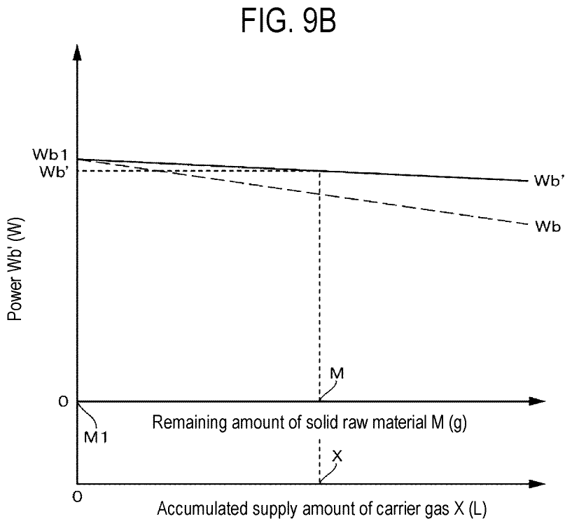

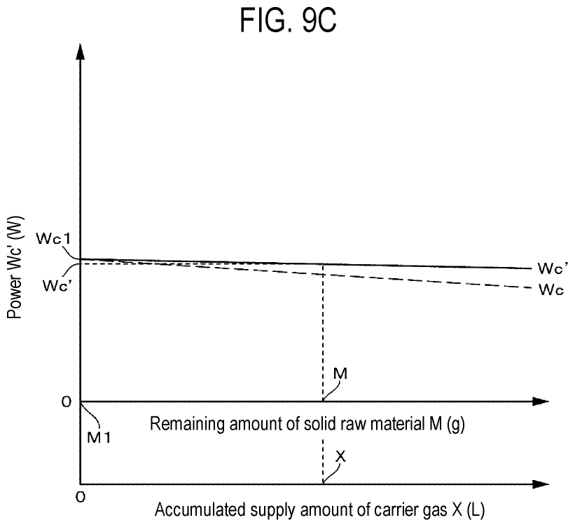

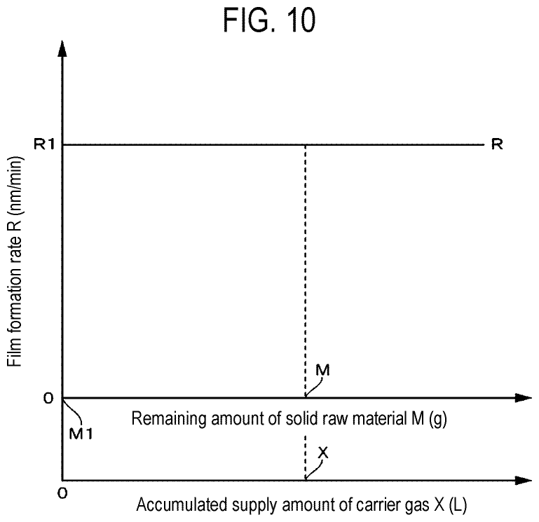

Hereinafter, operations in the raw material gas supply process in the present disclosure is described in detail with reference to FIGS. 7 to 10. FIG. 7 is a block diagram illustrating a raw material gas supply source of the present disclosure. FIG. 8 is a functional diagram of the raw material gas supply process of the present disclosure. In FIG. 8, a flow of the CO gas is represented by a solid line, and a flow of the raw material gas, which is the mixed gas of the CO gas and the DCR gas that is generated by the sublimation of the solid raw material S, is represented by a dashed line. In FIGS. 7 and 8, illustration of a portion of a downstream end at which the introduction path 13b is branched is omitted. FIGS. 9A to 9C are graphs showing changes in the powers of the respective heaters with respect to the remaining amount of the solid raw material in the same process, and FIG. 10 is a graph showing a change in the Ru film formation rate with respect to the remaining amount of the solid raw material in the same process.

In performing the raw material gas supply process, a power supply recipe for each heater 12 in the raw material gas supply process is created through a preliminary test. Specifically, the power supply recipe for each heater 12 that is necessary to maintain a film formation rate R1 at each remaining amount of the solid raw material S is created as the remaining amount of the solid raw material S changes. For example, at a start of Ru film formation when supply of the raw material gas to the wafer W is initiated, for example, an initial remaining amount M1=2500 g of the solid raw material S is accommodated at the beginning in the raw material container 11. The pressure inside the raw material container 11 and a supply amount of the CO gas per unit time may be kept constant or may be varied according to a change in the remaining amount of the solid raw material S. The pressure may be, for example, approximately 40 mTorr to 150 mTorr. On the other hand, no fixed set temperature is provided for the raw material container 11 and the temperature is determined according to the supply power. Therefore, the temperature sensors TCa, TCb, and TCc are used to monitor the temperatures of the bottom 14a, the side 14b, and the top cover 15. A target film formation rate R1 may also be referred to as a set film formation rate R1.

In the raw material gas supply process of the present disclosure illustrated in FIG. 7, for example, after the wafer W is loaded into the processing container 41, the powers are supplied to the heaters 12 and, at the same time, the valves V1 and V4 are closed and the valves V2, V3, and V6 are opened. The flow rate controller 13c of the carrier gas supply 13 starts supplying CO gas heated to a predetermined temperature (e.g., 80 degrees C.) at a preset flow rate. Subsequently, the vacuum exhauster 44 performs a vacuum exhaust operation and causes a carrier gas to flow into the raw material container 11 via the gas supply path 59. Additionally, powers adjusted by the power supplies 21a to 21c are supplied to the respective heaters 12a to 12c to heat the raw material container 11 and the solid raw material S.

When the temperature of the raw material container 11 becomes constant, the valve V6 is closed while the valve V1 is opened to start supplying the raw material gas from the raw material gas supply source 10 to the processing container 41. During the Ru film formation process, i.e., until the valve V1 is closed after the valve V1 is opened, the carrier gas supply 13 continues to supply the carrier gas to the raw material container 11 at a constant flow rate. Additionally, during the film formation of the Ru film, the temperatures of the raw material container 11, the gas supply path 59, the exhaust path 60, and the processing container 41 are constantly heated by the above-described heaters so as to be kept constant at the predetermined temperatures at least so that the raw material gas does not re-solidify.

Hereinafter, a raw material gas generation process is described. As shown by the solid line in FIG. 8, the CO gas supplied from the introduction path 13b first flows into the carrier gas flow path 19 via the carrier gas supply port 15b. The cylindrical carrier gas flow path 19 has a reduced width in the radial direction in a region below an upper end. As a result, the CO gas introduced to the upper end is prevented from flowing straight downward, flows in the circumferential direction, and flows downward from an entire circumference of the upper end. The CO gas flowing downward along the entire circumference of the carrier gas flow path 19 flows into the carrier gas introduction holes 17e that are open at an outer surface of the raw material loader 16.

The CO gas flowing into the carrier gas introduction holes 17e is supplied from all directions at intervals of 30 degrees C. to the raw material gas generation spaces SP of the vertically arranged trays 17. The CO gas then diffuses toward central and circumferential directions in a radial direction in the raw material gas generation spaces SP, circulating over the annularly disposed solid raw materials S. Therefore, the DCR gas, which is obtained from the sublimation of the solid raw materials S heated within the raw material container 11, and the CO gas are mixed in the raw material gas generation spaces SP, producing a raw material gas with a uniform concentration. The “DCR gas” corresponds to a “raw material in a raw material gas” in the claims.

The produced raw material gas flows toward the gaps 17d in the annular raw material gas generation spaces SP and is introduced from the gaps 17d into the central flow path 18. The DCR gas introduced into the central flow path 18 flows upward through the central flow path 18 and then through the raw material gas discharge port 15a and flows toward the gas supply path 59 and the shower head 50. Then, the CO gas introduced into the shower head 50 is discharged into the processing container 41 so as to be uniformly distributed over the surface of the wafer W. Then, an Ru film is uniformly formed on the surface of the wafer W at approximately the set film formation rate R1. From this perspective, the processing container 41 of the Ru film formation processing module 104 corresponds to a consumption zone of the raw material gas in the present embodiment. In the present disclosure, in order to form the Ru film while maintaining the set film formation rate R1 even when the solid raw material decreases, the powers supplied to the heaters 12, which decrease along with the reduction of the remaining amount of the solid raw material, are controlled so as to supply the raw material gas at a constant amount.

In the aforementioned preliminary test, powers capable of achieving the set film formation rate R1 are first supplied to the heaters 12 in a state in which the initial remaining amount M1 of the solid raw material S is accommodated. As described with reference to FIGS. 5 and 6, the powers Wa1, Wb1, and Wc1 supplied respectively to the heaters 12a, 12b, and 12c that are capable of achieving the set film formation rate R1 under the initial remaining amount M1 are identified in advance. Then, when the film formation on the wafer W in the preliminary test is sequentially continued in this manner, a film formation rate R changes. For example, if the film formation is continued without changing the powers Wa1, Wb1, and Wc1 supplied to the heaters 12, the film formation rate R becomes higher than the set film formation rate R1.

Therefore, the film formation is performed while sequentially lowering the powers supplied to the heaters 12 and powers Wa2, Wb2, and Wc2 that achieve the set film formation rate R1 at a current time point are specified. Once the supply powers Wa2, Wb2, and Wc2 are specified, a remaining amount M2 of the solid raw material S at that time point is measured. Thereafter, if the above-described operation is repeated, as shown in FIGS. 9A to 9C, a corresponding relationship between the remaining amount M of the solid raw material S in the raw material container 11 and powers Wa′, Wb′, and Wc′ supplied to the heaters 12 in achieving the set film formation rate R1 are obtained.

In FIGS. 9A to 9C, changes in the supply powers Wa, Wb, and Wc according to the comparative example described with reference to FIG. 6 are represented by dashed lines. Comparing the powers supplied represented by the dashed lines (comparative example) with the powers supplied represented by the solid lines (present disclosure) in these figures, it can be said that an offset correction, in which the powers supplied to the heaters 12 are increased as the amount of the solid raw material S inside the raw material container 11 decreases, is performed.

Meanwhile, in actual film formation processing, there may be a case where it is not possible to measure the remaining amount M of the solid raw material S over time. However, if the set film formation rate R1 is normally maintained, a consumption rate of the solid raw material S and a concentration of the DCR gas in the raw material gas are constant. In this case, when an accumulated supply amount X of a carrier gas [L (standard state)] supplied to the raw material container 11 from the flow rate controller 13c of the carrier gas supply 13 is discerned, it is possible to identify a consumption amount N of the solid raw material S. In addition, by subtracting the consumption amount N from the initial remaining amount M1 of the solid raw material S, it is possible to identify the remaining amount M at that time point. Therefore, it is possible to replace the corresponding relationship between the remaining amount M of the solid raw material S and the powers Wa′, Wb′, and Wc′ supplied to the respective heaters 12 in FIGS. 9A to 9C with a corresponding relationship with the accumulated supply amount X of the carrier gas.

Accordingly, a corresponding relationship between the accumulated supply amount X of the carrier gas and the powers Wa′, Wb′, and Wc′ supplied to the respective heaters 12 in FIGS. 9A to 9C is stored in the memory 201 of the controller 200 as a table. Based on the accumulated supply amount X of the carrier gas that increases at the film formation on the wafer W progresses, the powers Wa′, Wb′, and Wc′ corresponding to that accumulated supply amount X are supplied to the respective heaters 12.

The operation of the substrate processing system 1, which executes a series of processes including the above-described raw material gas supply process, is described with reference to FIGS. 1 and 2. At the start of the series of processes in the substrate processing system 1, recesses for forming wiring layers in a previously performed etching process are formed on the surface of the wafer W. The recesses are provided to reach, for example, a silicon (Si) layer and, when the wafer W is transferred, the recesses come into contact with an ambient atmosphere and thus a silicon oxide film formed by natural oxidation of the Si layer is formed on bottoms of the recesses.

When this wafer W is received by the vacuum transfer mechanism 69 inside the first vacuum transfer module 63 from the load lock module 62 shown in FIG. 1, the vacuum transfer mechanism 69 transfers the wafer W toward the COR processing module 101.

In the COR processing module 101, an inside of the processing container is pre-adjusted to a vacuum atmosphere by the vacuum exhauster. By opening the gate valve G1 of the COR processing module 101, the vacuum transfer mechanism 69 introduces the wafer W into the processing container from the loading port. The vacuum transfer mechanism 69 transfers the wafer W to the substrate stage. Then the vacuum transfer mechanism 69 is withdrawn from the processing container, and the gate valve G1 is closed. Pressure and temperature inside the processing container are adjusted according to recipe setting in the COR process. Subsequently, a mixed gas of HF gas and NH₃ gas for the COR process is supplied into the processing container 41. Therefore, the silicon oxide film is modified to form a reaction product.

When the COR process is completed, the wafer W on which the reaction product has been formed is unloaded from the COR processing module 101 in a reverse order to loading into the COR processing module 101. The wafer W is then transferred to the PHT processing module 102. In the same sequence as the loading into the COR processing module 101, the wafer W is loaded into the PHT processing module 102, and the PHT process is performed. Pressure and temperature inside the processing container are adjusted according to a recipe in the PHT process, and an inert gas is supplied to thermally treat the wafer W. A reaction product on the thermally treated wafer W sublimates, thereby removing the silicon oxide film and exposing the Si layer, which has not been oxidized, at the bottoms of the recesses.

After the PHT process is completed, the wafer W, from which the silicon oxide film has been removed, is unloaded from the PHT processing module 102 and is similarly loaded into the TiN film formation processing module 103 to perform the TiN film formation process. Pressure and temperature inside the processing container are adjusted according to a recipe in the TIN film formation process, and a raw material gas and a reaction gas are alternately supplied to form a TiN film in the recesses. When the wafer W is transferred from the PHT processing module 102 to the TiN film formation processing module 103, since the wafer W is transferred via the first vacuum transfer module 63, which is a transfer path of a vacuum atmosphere, the wafer W is not exposed to the ambient atmosphere. Accordingly, it is possible to suppress re-oxidization of the surface of the exposed Si layer inside the recesses by the ambient atmosphere.

After the TiN film formation process is completed, the wafer W on which the TiN film has been formed in the recesses is unloaded from the TiN film formation processing module 103 and similarly loaded into the Ru film formation processing module 104. When the wafer W is transferred from the TiN film formation processing module 103 to the Ru film formation processing module 104, since the wafer W is transferred via the first vacuum transfer module 63, the second vacuum transfer module 64, and the connection modules 65, which are transfer paths of the vacuum atmosphere, it is possible to transfer the wafer W on which the TiN film has been formed without exposure to the ambient atmosphere.

The Ru film formation process is performed on the wafer W loaded into the Ru film formation processing module 104. Since the valve V1 is in a closed state in the Ru film formation processing module 104 before the wafter W is loaded, N₂ gas is directly supplied into the processing container 41 from a N₂ gas supply which is not shown and, based on a measurement result from the pressure measurer P2, an opening degree of the APC valve provided at the vacuum exhaust path 43 is adjusted. As a result, the inside of the processing container 41 becomes a vacuum atmosphere at a predetermined pressure (e.g., 7 to 10 Torr).

In this state, the gate valve G1 provided at the wafer loading/unloading port of the processing container 41 is opened, and the vacuum transfer mechanism 69 that holds the wafer W is inserted into the processing container 41 from the second vacuum transfer module 64 via the loading/unloading port. The wafer W is then transferred above the substrate stage 42 described above, which is positioned at a standby location. Subsequently, the wafer W is transferred onto the raised support pins (not shown). Thereafter, the vacuum transfer mechanism 69 is unloaded from the processing container 41, and the gate valve G1 is closed. At the same time, the support pins are lowered, and the wafer W is placed on the substrate stage 42.

Next, the wafer W is heated to a predetermined temperature (e.g., 120 to 250 degrees C.) by the heater provided in the substrate stage 42. When the temperature of the wafer W reaches the predetermined temperature, the opening degree of the APC valve of the vacuum exhaust path 43 is adjusted so that the pressure inside the processing container 41 is reduced to a predetermined pressure (e.g., 5 mTorr to 100 mTorr). Once the pressure inside the processing container 41 is reduced, the raw material gas supply process is performed by the raw material gas supply source 10 so as to cause the gas supply mechanism 58 to start supplying the raw material gas into the processing container 41.

Meanwhile, the controller 200 sequentially processes the wafer W over a period until the remaining amount of the solid raw material S reaches a preset lower limit from the start of use of the raw material container 11 in which the initial remaining amount M1 of the solid raw material S, which is a specified amount, is accommodated. As a result, the accumulated supply amount X of the carrier gas supplied to the raw material container 11 is identified (process of obtaining the accumulated supply amount). Based on the corresponding relationships shown in FIGS. 9A to 9C, the supply powers Wa′, Wb′, and Wc′ corresponding to the accumulated amount X of the carrier gas at a current time point are supplied to the respective heaters 12. Consequently, the solid raw material S heated inside the raw material container 11 sublimates (process of sublimating the solid raw material), and the DCR gas, which is the raw material obtained by sublimation, and the CO gas, which is a carrier gas, are discharged from the raw material container 11 as a mixed raw material gas (process of supplying the raw material gas). At the same time, when the valve V1 in the gas supply path 59 is opened and an opening degree of the valve V2 is adjusted, the raw material gas is supplied into the processing container 41 via the shower head 50, and Ru film formation is initiated on the wafer W by CVD (Chemical Vapor Deposition).

As already described, the powers Wa′, Wb′, and Wc′ supplied to the respective heaters 12 are adjusted so as to maintain the set film formation rate R1 even when the remaining amount of the solid raw material S inside the raw material container 11 changes. Therefore, a raw material gas with a uniform concentration of the DCR gas is supplied to each wafer W on which the film formation process is sequentially performed in the Ru film formation processing module 104, thereby stably forming the Ru film across the surface of the wafer W under the condition of the set film formation rate R1. Even during the film formation of each wafer W, the powers Wa′, Wb′, and Wc′ supplied to the heaters 12 may be adjusted at any time as the accumulated supply amount X of the carrier gas increases. Also, intermittent supply power adjustment may be performed where, until starting film formation on the next wafer W, the powers Wa′, Wb′, and Wc′ supplied to the respective heaters 12 are set based on the accumulated supply amount X of the carrier gas up to that point, and the supply powers are fixed during a processing period of the wafer W.

Once the Ru film formation process is completed, the valve V1 becomes a closed state, and the wafer W is unloaded from the processing container 41 in a reverse order to the above procedure, loaded to the load lock module 62, and then returned back to the transfer container C via the loader module 61.

According to the present disclosure as described above, it is possible to supply the raw material gas such that a desired film formation rate is obtained. That is, even when the remaining amount M of the solid raw material S in the raw material container 11 changes, the powers to be supplied to the respective heaters 12 are identified in advance by the preliminary test so as to maintain the set film formation rate R1. The supply powers are correlated with the accumulated supply amount X of the carrier gas, which serves as an index for estimating the remaining amount M of the solid raw material S in the raw material container 11. Based on this corresponding relationship, powers are supplied to the respective heaters 12a to 12c during the film formation process on the wafer W. As a result, an effect of the change in the heat capacity accompanied by the change in the remaining amount M of the solid raw material S is reduced, making it possible to achieve stable film formation at the set film formation rate R1. Further, according to supply power adjustment based on the corresponding relationship of the present disclosure, it is possible to continuously supply the raw material gas until the remaining amount of the solid raw material S reaches approximately zero, while controlling to be at the set film formation rate R1 (specifically, within an allowable range including the set film formation rate R1). Therefore, it is possible to extend an exchange cycle of the solid raw material S for replenishing or replacing the solid raw material S.

In this operation, although the carrier gas is supplied continuously at a constant flow rate in the present disclosure, this is not an essential requirement. For example, the carrier gas may be supplied intermittently during the film formation process such as ALD (Atomic Layer Deposition), or the flow rate of the carrier gas may be varied during the film formation process. Even in such a case, it is possible to appropriately identify the accumulated supply amount by the flow rate controller 13c of the carrier gas supply 13 or a flow meter which is newly provided, for example, in the introduction path 13b. However, when the flow rate of the carrier gas is varied, the corresponding relationship shown in FIGS. 9A to 9C needs to be changed according to the flow rate of the carrier gas, as described later, in order to prevent changes in the concentration of the DCR gas in the raw material gas.

In addition, in this operation, it is not essential that the accumulated supply amount used as a reference when supplying the powers, as described in the present disclosure, be measured during the raw material gas supply process. For example, if the supply amount of the carrier gas is set in advance to be constant per unit time as in the present disclosure, it is possible to predict the accumulated supply amount in advance without obtaining the accumulated supply amount sequentially during the raw material gas supply process. Therefore, the powers supplied to the respective heaters 12 may be adjusted based on the predicted accumulated supply amount without measuring the accumulated supply amount of the carrier gas.

Moreover, when the same film formation process is repeatedly performed on multiple wafers W, similar power adjustment is possible even without predicting in advance or measuring the accumulated supply amount of the carrier case for each wafer W. Specifically, the powers may be supplied in the same manner as for the wafer W on which film formation has been performed previously, without identifying the accumulated supply amount for each wafer W. Additionally, as described in the present disclosure, it is not essential to regularly measure the accumulated supply amount and adjust the supply powers at constant intervals, and the accumulated supply amount may be intermittently measured and may be measured at the end of a previous carrier gas supply period in the case of a carrier gas supply pattern involving repetition of supply and cutoff of the gas. Further, it is not essential that the measurement and the supply power adjustment be executed on a one-to-one basis, and either of the measurement or the supply power adjustment may be performed more frequently.

The corresponding relationship between the accumulated supply amount of the carrier gas and the supply power changes, for example, if the supply flow rate of the carrier gas per unit time is varied. Therefore, when the supply flow rate of the carrier gas is varied, a corresponding relationship corresponding to each supply flow rate is acquired. A plurality of corresponding relationships (tables) obtained at a plurality of different flow rates are then stored in the memory 201 of the controller 200. Accordingly, when the flow rate of the carrier gas is varied, it is possible for the controller 200 to switch between corresponding relationships used to adjust the powers supplied to the heaters 12, thereby enabling execution of appropriate power supply.

Moreover, the corresponding relationships may be obtained for various conditions regarding the initial remaining amount M1 or form of the solid raw material S, a type of the carrier gas, the set film formation rate R1, a recipe, other set values, and the like. For example, taking the set film formation rate R1 as an example, if corresponding relationships for different set film formation rates (R)x (x=1, 2, 3, . . . ) are obtained, it is possible to appropriately adjust a film formation rate in the film formation process. Further, if a plurality of different corresponding relationships are obtained, it is possible to use a corresponding relationship by interpolating or extrapolating the corresponding relationships, for example, by numerical processing.

In the above-described embodiment, the supply power adjustment is performed based on the corresponding relationship between the accumulated supply amount and the powers supplied to the heaters 12 using the accumulated supply amount of the carrier gas as an index value indicating the remaining amount of the solid raw material S. However, an example of the index value is not limited thereto. For example, a weight of the raw material container 11 in which the solid raw material S is accommodated may be used as the index value indicating the remaining amount of the solid raw material S. In this case, the supply powers are adjusted based on pre-acquired corresponding relationships between the weight of the raw material container 11 in which the solid raw material S is accommodated and the supply powers.

An actual film formation rate, which is adjusted to the set film formation rate R1 through the above-described power supply adjustment is not necessarily limited to being controlled at a fixed value. For example, the film formation rate may be controlled within an allowable range so that a film thickness after the film formation remains within a manageable value. Further, it is desirable that the power supply adjustment be performed within, for example, a range of ±10% of the supply powers Wa′ to Wc′ according to the corresponding relationship. The supply power adjustment is not limited to continuously varying the power values as shown in FIGS. 9A to 9C, and the power values may also be changed in a stepwise manner as fixed values. Additionally, the supply power adjustment may be performed by appropriately turning on and off the power supply, so that an amount of heat supplied to the raw material container 11 is changed in the same manner as the power values are changed.

While it is desirable that the adjustment of the supply powers using the corresponding relationship as described above is performed with respect to all of the heaters 12a to 12c, it may be unnecessary to adjust the supply powers with respect to some of the heaters 12, such as the top heater 12c. The heaters 12 do not necessarily need to be provided at the bottom 14a, the side 14b, and the top cover 15, respectively, and a single heater 12 may be provided at, for example, a lower side of the raw material container 11. Further, it is not necessary to provide the temperature sensors TCa to TCc corresponding respectively to the heaters 12 and, for example, a single temperature sensor may be provided corresponding to one of the heaters 12 to monitor the temperature of the raw material container 11. In addition, during this adjustment of the supply power, the inside of the raw material container 11 is depressurized by the vacuum exhauster 44 via the exhaust path 60, but this depressurization is not a mandatory requirement and the inside of the raw material container 11 may be at a constant pressure.

The raw material gas is not limited to the mixed gas of the DCR gas and the CO gas and a mixed gas of a gas containing a raw material of a film to be formed on the wafer W and a carrier gas selected according to this gas may be appropriately selected. Specifically, a gas obtained by the sublimation of a solid raw material may be, for example, aluminum chloride (AlCl₃) gas containing a raw material of an aluminum nitride (AlN) film or tungsten chloride (WCl₅) gas containing a raw material of a tungsten (W) film, etc. In such a case, a reaction gas is supplied to the processing container 41. The carrier gas may be an inert gas such as N₂ gas in addition to the CO gas.

It should be noted that the embodiments disclosed herein are exemplary in all aspects and are not restrictive. The above-described embodiment may be omitted, replaced, modified, or combined in various forms without departing from the scope and spirit of the appended claims.

According to the present disclosure in some embodiments, it is possible to supply a raw material gas so as to obtain a desired film formation rate by controlling power supplied to a heater based on a corresponding relationship between a heating temperature of a raw material and a supply amount of a carrier gas.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of supplying a raw material gas, comprising:
supplying a power to at least one heater provided at a raw material container in which a solid raw material is accommodated and heating an inside of the raw material container to sublimate the solid raw material;
supplying a carrier gas to the raw material container being heated by the at least one heater and mixing the carrier gas with the sublimated solid raw material to supply a mixed gas as the raw material gas to a consumption zone in which a substrate is disposed; and
acquiring an index value having a corresponding relationship with a remaining amount of the solid raw material,
wherein, in sublimating the solid raw material, a power corresponding to the index value is supplied to the at least one heater, based on a corresponding relationship between the index value, which is preset, and the power supplied to the at least one heater.

2. The method of claim 1, wherein the index value is an accumulated supply amount obtained by accumulating a supply amount of the carrier gas supplied to the raw material container.

3. The method of claim 2, wherein, in obtaining the accumulated supply amount, the supply amount of the carrier gas is accumulated over a period until the remaining amount of the solid raw material reaches a preset lower limit from start of use of the raw material container in which a specified amount of the solid raw material is accommodated.

4. The method of claim 2, wherein a corresponding relationship between the accumulated supply amount of the carrier gas and the power supplied to the at least one heater is set so that a supply amount per unit time of a raw material in the raw material gas supplied to the consumption zone becomes a preset value.

5. The method of claim 1, wherein a plurality of stages of raw material holding trays spaced apart from each other in a vertical direction is provided inside the raw material container, the solid raw material is held on each of the raw material holding trays, and the carrier gas supplied to the raw material container passes over the raw material holding trays and is mixed with the sublimated solid raw material.

6. The method of claim 1, wherein the at least one heater includes a plurality of heaters provided at different positions of the raw material container, and a corresponding relationship is set between the index value and a power supplied to each of the plurality of heaters.

7. An apparatus for supplying a raw material gas, comprising:
a raw material container configured to accommodate a solid raw material and including at least one heater configured to heat the solid raw material;
a power supply configured to supply a power to the at least one heater;
a carrier gas supply configured to supply a carrier gas to the raw material container;
an index value calculator configured to calculate an index value having a corresponding relationship with a remaining amount of the solid raw material;
a raw material gas flow path configured to supply the raw material gas obtained from the raw material container to a consumption zone in which a substrate is disposed; and
a controller,
wherein the controller is configured to generate a control signal for executing a process including:
supplying the power to the at least one heater and heating an inside of the raw material container to sublimate the solid raw material;
supplying the carrier gas to the raw material container being heated by the at least one heater and mixing the carrier gas with the sublimated solid raw material to supply a mixed gas as the raw material gas to the consumption zone; and
calculating the index value, and
wherein, in sublimating the solid raw material, the controller is configured to supply a power corresponding to the index value to the at least one heater, based on a corresponding relationship between the index value, which is preset, and the power supplied to the at least one heater.

8. The apparatus of claim 7, wherein the index value calculator is a supply amount accumulator configured to obtain, as the index value, an accumulated supply amount by accumulating a supply amount of the carrier gas supplied from the carrier gas supply.

9. The apparatus of claim 8, wherein, in obtaining the accumulated supply amount, the supply amount of the carrier gas is accumulated over a period until the remaining amount of the solid raw material reaches a preset lower limit from start of use of the raw material container in which a specified amount of the solid raw material is accommodated.

10. The apparatus of claim 8, wherein a corresponding relationship between the accumulated supply amount of the carrier gas and the power supplied to the at least one heater is set so that a supply amount per unit time of a raw material in the raw material gas supplied to the consumption zone becomes a preset value.

11. The apparatus of claim 7, wherein a plurality of stages of raw material holding trays spaced apart from each other in a vertical direction is provided inside the raw material container, the solid raw material is held on each of the raw material holding trays, and the carrier gas supplied to the raw material container passes over the raw material holding trays and is mixed with the sublimated solid raw material.

12. The apparatus of claim 7, wherein the at least one heater includes a plurality of heaters provided at different positions of the raw material container, and a corresponding relationship is set between the index value and a power supplied to each of the plurality of heaters.

13. An apparatus for forming a film on a substrate, the apparatus comprising:
the apparatus for supplying the raw material gas of claim 7; and
a processing container corresponding to the consumption zone and provided with a stage configured to dispose the substrate,
wherein the controller is configured to generate a control signal for executing a process of disposing the substrate on the stage and forming the film on the substrate by the raw material gas supplied to the processing container from the apparatus for supplying the raw material gas.
